(19) United States
(12) Patent Application Publication
(10) Pub. No.: US 2015/0180408 A1
(43) Pub. Date: Jun. 25, 2015

(54) SYSTEMS AND METHODS FOR DETECTING DISCONTINUITIES IN A SOLAR ARRAY CIRCUIT AND TERMINATING CURRENT FLOW THEREIN

(71) Applicant: DOW GLOBAL TECHNOLOGIES LLC, Midland, MI (US)

(72) Inventors: Stephen G. Pisklak, Hockessin, DE (US); Douglas J. Wirsing, Midland, MI (US)

(21) Appl. No.: 14/413,315

(22) PCT Filed: Jun. 26, 2013
(86) PCT No.: PCT/US2013/047841

§ 371 Date: Jan. 7, 2015

Related U.S. Application Data
(60) Provisional application No. 61/669,415, filed on Jul. 9, 2012.

(51) Int. Cl. H02S 50/10; G01R 31/02

(52) U.S. Cl. CPC H02S 50/10; G01R 31/026

(57) ABSTRACT

The technology relates to a solar array kit useful in forming a solar array system, including a continuity signal generator and a detection circuit. The continuity signal generator has connectors for connecting to a solar array circuit and delivers a continuity signal to the solar array circuit. The detection circuit has connectors for connecting to the solar array circuit, a continuity signal sensor, at least one switch for selectively opening and closing the solar array circuit, and a switch controller. The switch controller has connectors for connecting to a power source and is adapted to actuate the switch upon receipt of a control signal from the detection circuit.

This application is being filed on 26 Jun. 2013, as a PCT International Patent application and claims priority to U.S. Patent Application Ser. No. 61/669,415 filed on 9 Jul. 2012, the disclosure of which is incorporated herein by reference in its entirety.

### INTRODUCTION

The 2011 National Electric Code (NEC) 690.11 includes a requirement to both detect and suppress an electrical arc in connection with new photovoltaic installations. Frequently, conventional rack mounted solar panels are strung together in such a way that breaking the circuit is sufficient to extinguish an arc. In these systems, it is uncommon for voltage potentials greater than 100V to be present in the same panel. Accordingly, the photovoltaic industry has focused on detecting and suppressing series arcs. However, as alternative photovoltaic designs and installations are developed, including designs where the photovoltaic article also serves as building cladding (sometimes referred to as building integrated photovoltaics or BIPV), certain system and array designs may lead to relatively high voltage potentially in nearby electrical bus lines. In certain arrays constructed of multiple BIPV articles, however, the home-run bus runs parallel to the operating bus, and some shingles may have up to 600V potential between the two busses. In such a case, both series and parallel arcing are theoretically possible.

### SUMMARY

In one aspect, the technology relates to a solar array kit useful in forming a solar array system, the kit including: a continuity signal generator having connectors for connecting a solar array circuit, wherein the continuity signal generator is adapted to deliver a continuity signal to the solar array circuit; and a detection circuit having connectors for connecting to the solar array circuit, the detection circuit including: a continuity signal sensor; at least one switch for selectively opening and closing the solar array circuit; and a switch controller operatively connected to the switch and the continuity signal sensor, wherein the switch controller includes a connector for connecting to a power source, and wherein the switch controller is adapted to actuate the switch upon receipt of a control signal from the detection circuit. In one embodiment, the solar array kit includes at least one solar cell having connectors for connecting to the solar array circuit and the detection circuit. In another embodiment, the control signal includes the continuity signal. In yet another embodiment, the detection circuit further includes an amplifier for amplifying a solar array signal and a filter for filtering the solar array signal, and wherein the solar array signal includes the continuity signal. In still another embodiment, the switch controller connector is adapted to connect to a power source discrete from the solar array circuit.

In another embodiment of the above aspect, the switch controller connector is adapted to connect to the solar array circuit, wherein the solar array circuit is adapted to deliver power to the switch. In yet another embodiment, the power source discrete from the solar array circuit has at least one of: discrete solar power generation cell including connectors for connecting to the switch controller connector; and a magnetic flux generator including a first inductor and a second inductor, the first inductor and second inductor arranged so as to generate a magnetic flux between the first inductor and the second inductor, and wherein the second inductor has connectors for connecting to the switch controller connector. In still another embodiment, the at least one switch includes at least one of a metal-oxide-semiconductor field-effect transistor, a solid-state switch, and a mechanical switch.

In another embodiment of the above aspect, the continuity signal sensor includes at least one of a transformer, an antenna, and a hard-wire connection.

In another aspect, the technology relates to a method for maintaining a solar array circuit, the method including: detecting a solar array signal on a solar array circuit; and sending a control signal to a solar array circuit switch, based on the presence of a continuity signal in the solar array signal. In one embodiment, the method further includes: generating the continuity signal; and routing the continuity signal onto the solar array circuit. In another embodiment, the method further includes closing the solar array circuit upon receipt of the control signal. In yet another embodiment, the control signal includes the continuity signal. In still another embodiment, the solar array signal includes a direct current component, and wherein the continuity signal includes an alternating current component.

In another embodiment of the above aspect, the solar array signal is generated by at least one solar cell. In yet another embodiment, the method further includes at least one of filtering the detected solar array signal, amplifying the detected solar array signal, and rectifying the detected solar array signal. In still another embodiment, the method further includes delivering power to the switch from a power source discrete from the solar array circuit.

In another embodiment of the above aspect, the power source includes at least one of a solar cell discrete from the solar array circuit, a magnetic flux generator, and a building power service. In yet another embodiment, the method includes delivering power to the switch from the solar array circuit. In still another embodiment, the solar array signal is detected via at least one of an antenna, a transformer, and a hard-wire connection.

### BRIEF DESCRIPTION OF THE DRAWINGS

There are shown in the drawings, embodiments which are presently preferred, it being understood, however, that the technology is not limited to the precise arrangements and instrumentalities shown.

FIG. 1A is a schematic diagram of a solar array system.

FIG. 1B is a schematic diagram of a solar array system with a discontinuity detection and suppression system.

FIG. 1C is an enlarged view of the solar array of FIG. 1B.

FIG. 2 depicts schematic views of array circuits in various arc conditions.

FIGS. 3A-3B depict an embodiment of a solar array system with a discontinuity detection and suppression system.

FIG. 4 depicts another embodiment of a solar array system with a discontinuity detection and suppression system.

FIG. 5 depicts an embodiment of a solar array system with a discontinuity detection and suppression system.

FIGS. 6A-6B depict another embodiment of a solar array system with a discontinuity detection and suppression system.

FIG. 7 depicts a method for detecting a discontinuity and suppressing a current in solar array systems.

FIG. 8A depicts a computer system for use in the discontinuity detection and suppression systems described herein.

FIG. 8B depicts a network environment.

### DETAILED DESCRIPTION

The technology described herein has particular application in the residential solar market. Solar power generation modules may be building integrated solar modules, also referred to as a building integrated photovoltaics (BIPV), which may be used to replace conventional building materials in parts of a building envelope such as the roof, skylights, or facades. The module may be a thin film solar cell integrated to a flexible polymer roofing membrane, a module configured to resemble one or more roofing shingles (for example, the POWERHOUSE brand of BIPV shingles manufactured by the Dow Chemical Company), or semitransparent modules used to replace architectural elements commonly made with glass or similar materials, such as windows and skylights. Alternatively, the solar module may be a rigid solar module mounted to an architectural element such as a roof or installed within a large field array. In short, the technology is not limited to building integrated photovoltaic or arrays having discrete sensor modules and generator modules.

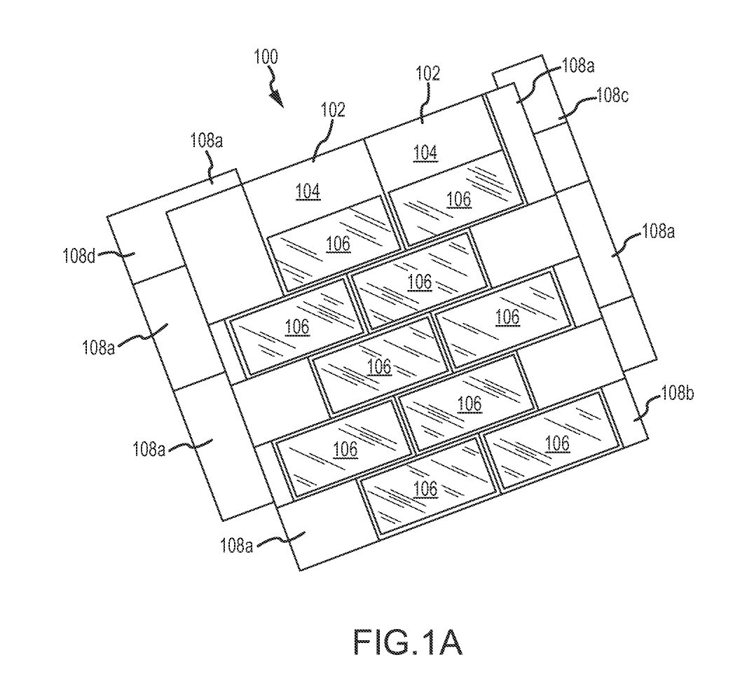

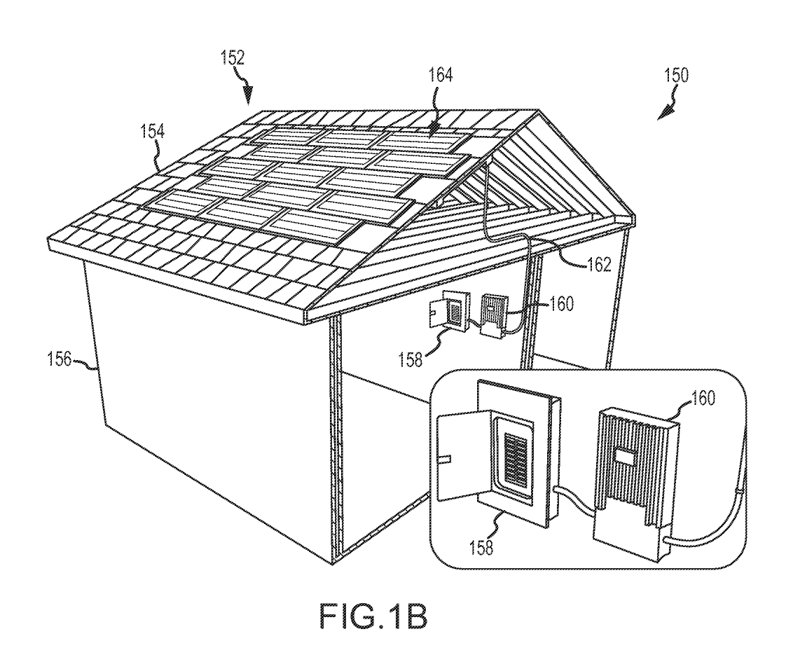

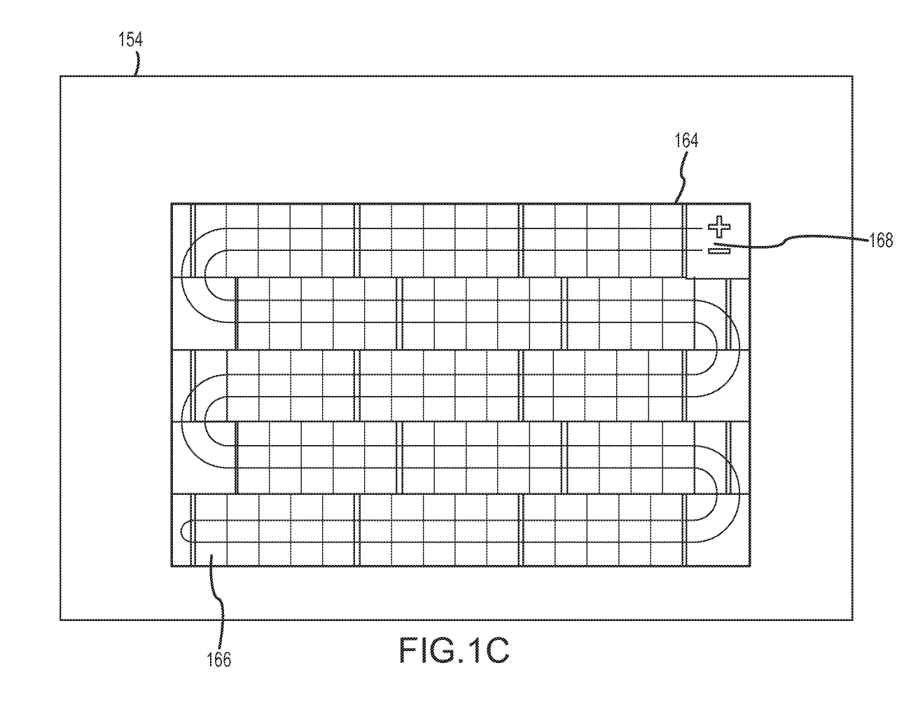

The systems for detecting discontinuities and suppressing current in a solar array system may be used with solar array systems utilizing BIPV articles, as well as in conventional rack mounted solar panels used in small arrays or large-scale field arrays. The unique advantages of the described systems make them particularly useful in BIPV array. Accordingly, that application is described herein. FIG. 1A depicts an installation of a solar array system 100 which may be used in conjunction with the systems and methods described herein. The system 100 includes a number of building integrated photovoltaic devices 102 that include both a body portion 104 and a photovoltaic cell module 106. The system 100 may include at least one edge piece 108a located at the end or within the at least two rows/columns of photovoltaic devices 102. Additionally, at least one starter piece 108b, at least one filler piece 108c, and at least one end piece 108d may be utilized. These components, as well as elements used for connection of these components, are described in International Publication Number WO 2009/137353, the disclosure of which is hereby incorporated by reference herein in its entirety.

FIG. 1B is a schematic diagram of an embodiment of a solar array system 150 including a discontinuity detection and suppression system. Such an embodiment is installed on a building or structure 152. In some embodiments, the structure may be a residential or commercial structure, a garage, a shed, or any other suitable structure for incorporating components disclosed herein. The structure 152 also includes a roof 154 and a support structure 156, such as walls. As depicted in FIG. 1B, the solar array system 150 includes a plurality of power generator modules 164, or solar modules. The plurality of power generator modules 164 are coupled to a discontinuity detection system 160 via a connection 162. The connection 162 is a wired connection. In some embodiments, the discontinuity detection system 160 may be housed within a control/monitoring system for the solar array system 150, which may include an inverter. In this embodiment, the discontinuity detection system 160 is also connected to power panel 158. It will be appreciated by those having skill in the art that the discontinuity detection system 160 need not be connected directly to the power panel 158.

FIG. 1C is an enlarged view of the solar array system 150 of FIG. 1B. The solar array system 150 includes a plurality of power-generator modules 164, on a roof 154 of a building 152. In the depicted embodiment, fifteen power-generator modules 164 are utilized. Any number of power-generator modules could be included, however, as desired for a particular application. For residential applications, the maximum array square footage is often limited by, for example, roof size. Each of the power-generator modules 164 contains five photovoltaic cells 166. A power circuit, or a solar array circuit, 168 connected to the power-generator modules 164 is wired in series, as typical for solar applications. Dimensions of the solar cells or power generation modules, as well as the number of photovoltaic cells contained in each, may differ as required or desired for a particular application. Array systems utilizing differently sized and configured modules are also contemplated. Other components of the array system 150 are described below.

Broadly described, the discontinuities detected with the technologies described herein may be indicative of two types of arc events. Series arcs occur when an open is established in one of the bus paths and the open is exposed to enough voltage to arc across the open. The series arc would occur somewhere on the “+” line bus or the “−” line bus. A parallel arc occurs when the bus voltage is sufficient to bridge the gap from the “+” bus to the “−” bus and therefore appears somewhere between the “+” bus and the “−” bus. Both types of arcs will degrade the circuit quality through the shingle array sufficiently to prevent communication of a control signal over the same circuit.

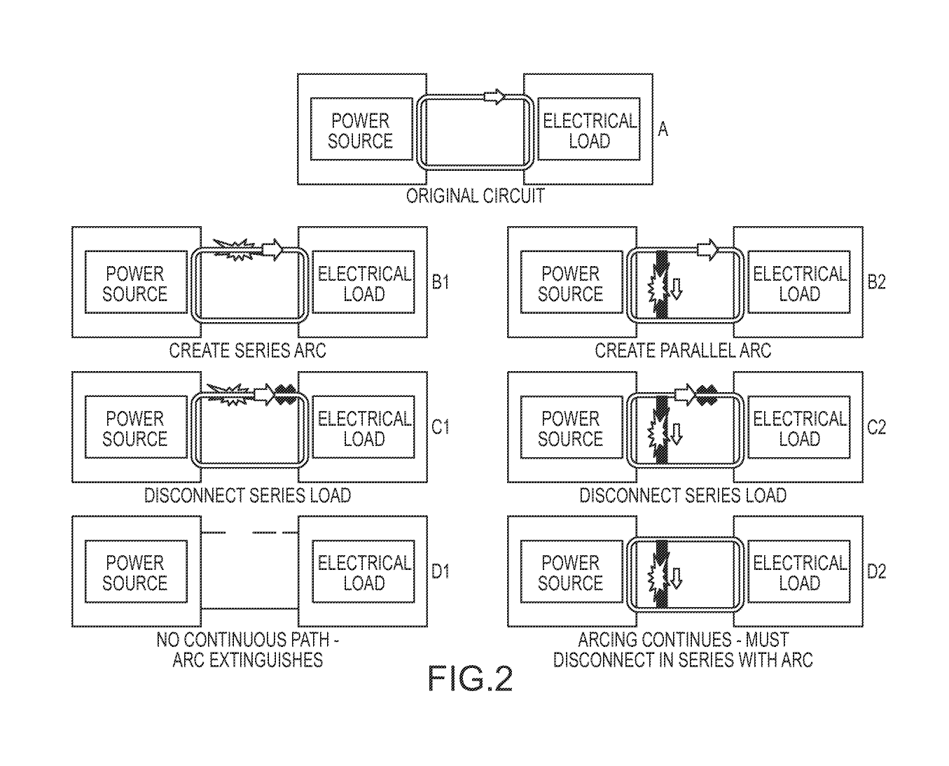

FIG. 2 depicts schematic views of array circuits in various conditions, and both series and parallel arcs are described in more detail in relation thereto. A basic operational circuit, which may be a solar array circuit, is depicted in Part A. The circuit includes power source (in an array circuit, this may be one or more solar cells, BIPV articles, etc.), a power conditioning circuit (such as a grid-tied inverter, DC-DC boost circuit, DC-DC buck circuit, or charge controller), and two lead wires or conductors connecting the source to the load. Part B depicts the two types of arcing, series and parallel. Series arcs are created by separation of two conductors carrying electrical current, as depicted in Part B1. The arc event is in series with the electrical load, wiring, etc. When the circuit is sufficiently suppressed (by opening the circuit or substantially reducing the current flow) at any point (see Part C1), the arc is extinguished, as depicted in Part D1. A parallel arc occurs between conductors, in this case, the two lead wires, initially at different voltages (say, 300 V and 0 V), as depicted in Part B2. Parallel arcs occur in parallel with another load, thus forming two loads, and the voltage drop across the arc and original load are determined by the current-voltage characteristics of the arc. If the original load is removed, the arc will not extinguish, as depicted in Part C2 and D2. The circuit must therefore be opened in a location in series with the circuit created by the arc. In the case of Part D2, extinguishing the arc would require opening the circuit on the remaining portions of lead wires between the arc and the power source. Installing disconnects or suppression devices, such as switches, at various locations on the array circuit allows successful breaking of the circuit and therefore suppression of the arc at the appropriate location to eliminate of the parallel arc, regardless of location of a parallel arc.

The systems and methods described herein detect discontinuities within the solar array circuit, such as those discontinuities caused by arc events or other anomalies within the solar array. More accurately, a composite signal, or solar array signal, passing through the solar array circuit is continuously monitored for anomalies that may indicate a potentially undesired condition within the circuit, i.e., an arc. This composite signal, or solar array signal, has two components. A primary component of the composite signal is from the power generated by the solar cells and is characterized by a direct current, as is typical for solar installations. A second component is a continuity signal having an alternating current that is generated remotely from the solar array circuit. In some embodiments the continuity signal may be a square wave, individual pulses, or any other signal known in the art. This continuity signal is overlaid onto the direct current power signal such that both components may be detected during operation of the solar array circuit. Anomalies detected in this composite signal, for example, an absence of the continuity signal in the composite signal, are indicative of an event such as an arc that requires termination of the circuit. In response to such an anomaly detection, the systems described herein break the circuit, thus terminating current flow therethrough and suppressing any arcing event that may be occurring. However, when the continuity signal is present in the solar array signal, the systems maintain the circuit in a closed condition, allowing current to flow. Accordingly, the systems and methods described herein may be referred to as discontinuity detection and arc suppression systems, even though arc suppression is a byproduct of breaking the solar array circuit.

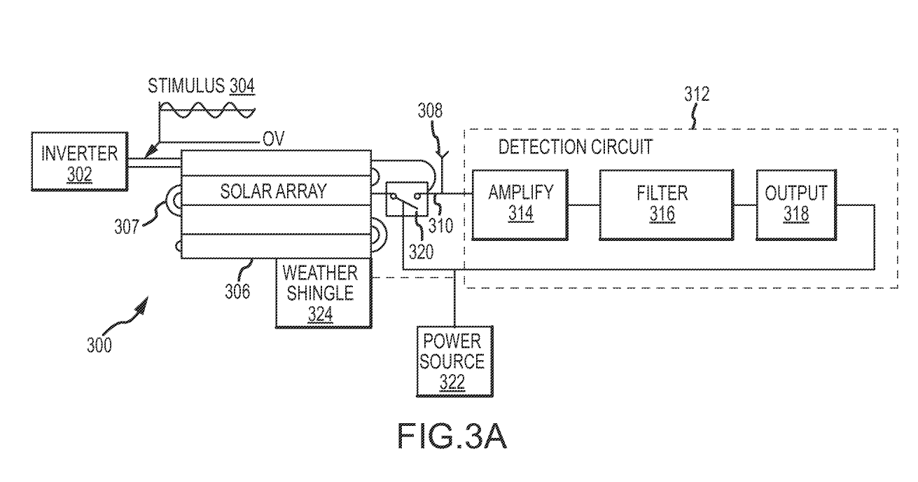

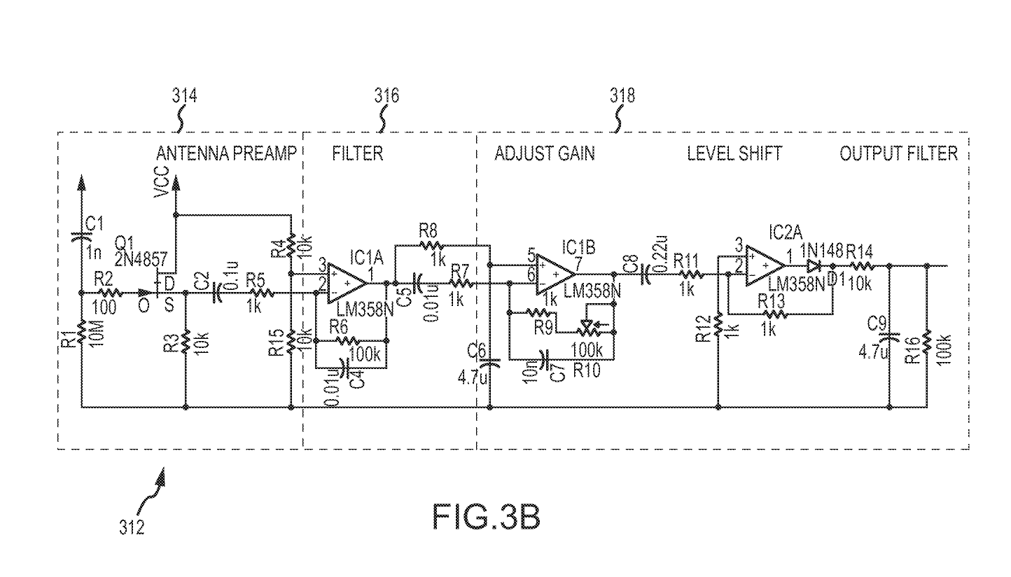

FIGS. 3A-3B depict an embodiment of a solar array system with a discontinuity detection and suppression system 300. The embodiment of the discontinuity detection and suppression system 300 depicted in FIG. 3A includes an inverter 302 which routes a continuity signal or stimulus 304 onto a solar array circuit 307. In embodiments, the inverter 302 may be controlled manually or remotely, via the internet or other communication network, allowing a user to discontinue the continuity signal or stimulus 302 for any reason. The stimulus 304 may be any type of identifiable signal known in the art, including an alternating current (AC) signal. A detection circuit 312 monitors a signal on the solar array circuit 307 via a continuity signal sensor. The continuity signal sensor may be, among other things, an antenna 308 and/or a wired connection 310. While monitoring the solar array circuit 307, the detection circuit 312 detects the presence of the stimulus 304 on the solar array circuit 307 utilizing several components. In some embodiments, these components include an amplifier 314, a filter 316, and an output 318. The detection circuit 312 may be physically located in many different locations, such as being housed remotely in the inverter 302 or into a starter piece located on or adjacent to the solar array 306. Multiple detection circuits 312 may also be used on a single solar array 306. For example, a detection circuit 312 may be included on each row of the solar array 306.

In embodiments where the signal on the solar array circuit 307 is monitored using an antenna 308, the amplifier 314 may be a preamplifier for the signal detected by the antenna 308. As it can be appreciated by those with skill in the art, preamplification of an antenna signal provides a more useful signal, however it is not necessary to process the signal. In an embodiment where the signal on the solar array circuit 307 is monitored using a hard-wire connection 310, the amplifier 314 may also amplify or attenuate the detected signal depending on the desired application. In both embodiments implementing an antenna 308 and/or a hard-wire connection 310, the amplifier 314 may include an operational amplifier (“op amp”) or any other amplification methods or components.

The filter 316 of the detection circuit 312 filters the detected signal after the detected signal has been amplified or attenuated by the amplifier 314. The filter 314 is used to filter the detected signal to facilitate the detection of the stimulus 304. For example, if the stimulus 304 has a relatively high frequency, the filter 316 may include a high-pass filter, thus allowing the high-frequency stimulus to pass through the filter. Depending on the application and the characteristics of the stimulus 304, a number of different filters could be implemented in the filter 316, including low-pass filters and band-pass filters, among others. Additionally, computer-implemented filtering programs, or other filtering methods and devices could be utilized.

The output 318 of the detection circuit 312 controls the output of detection circuit 312 and, in some embodiments, outputs a control signal to a switch 320. The output 318 may include circuitry to compare the filtered signal to a predetermined level to determine if the stimulus 304 is present. In such embodiments where the filtered signal is compared to a predetermined level, the output component 318 circuitry may include a comparator. Other methods and components for comparing characteristics of electric signals, such as voltage levels, current levels, frequencies, waveform shapes, etc. are contemplated. In certain embodiments where the output 318 detects the presence of the stimulus 304 within the detected composite signal from the solar array 306, the output 318 outputs a control signal to switch 320 indicating that the switch 320 should close or remained closed. In certain embodiments, the stimulus 304 is converted to a control signal by the output 318 instead of an independently generated control signal. In other embodiments, the output 318 allows for the stimulus signal to pass through to the switch 320 if the stimulus 304 is present. In such embodiments, the switch 320 will close or remain closed upon receipt of the stimulus 304. Where the stimulus 304 is not present, no signal will reach the switch, and the switch will open. Alternatively, the output 318 may continue to output a signal to the switch 320 indicating that switch 320 should remain closed for a period of time after the stimulus 304 is not detected on the solar array 306.

The switch 320 is connected to the solar array 306 in such a way that it can open the solar array circuit 307. Although the switch 320 has been depicted in FIG. 3A as located outside the detection circuit 312, in some embodiments the switch 320 may be a part of the detection circuit 312. The switch 320 remains closed when the stimulus 304 is present on the solar array circuit 307. When the stimulus 304 is not detected by the detection circuit 312, the switch 320 opens, thus breaking the solar array circuit 307. In certain embodiments, the switch 320 remains closed as long as the control signal or stimulus signal is received from the detection circuit 312, or more specifically, from the output 318. The switch 320, in some embodiments, is a transistor, such as a metal-oxide-semiconductor field-effect transistor (MOSFET), although other types of switches, such as mechanical, other solid-state, and computer-controlled switches are contemplated.

Two options for providing power to the detection circuit 312 and the switch 320 are depicted in FIG. 3A. A power source 322, such as power from a building, service panel, wall outlet, or battery may be utilized. In an alternative embodiment, power to the detection circuit 312 and the switch 320 may be provided by a discrete solar power generation cell or module 324, which also may be referred to as a weather shingle. One such discrete cell 324 is described in PCT Publication No. WO 2012/074808, entitled “Photovoltaic Device for Measuring Irradiance and Temperature,” the disclosure of which is hereby incorporated by reference herein in its entirety. The dimensions of this module 324 may be substantially the same as the solar cells used in the array 306 so as to be easily incorporated into the array 306. Modules 324 having sizes different than the cells in the array are also contemplated. One application where identical modules may be desirable are building integrated solar array systems, where aesthetics may be a significant determining factor. Such identical modules may be incorporated directly into the solar array 306, without detracting from installation aesthetics.

One example of a detection circuit 312 is depicted in FIG. 3B. The detection circuit 312 includes the amplifier 314 that contains an antenna preamp circuit utilizing a 2N4857 transistor. Following the amplifier 314, the filter 316 contains circuitry for filtering the amplified signal. This circuitry includes a standard LM358N op amp. Following the filter 316 circuitry, is the output 318 circuitry. As can be seen from the example depicted in FIG. 3B, this embodiment of the output 318 first adjusts the gain using another LM358N op amp. Then the level of the signal is adjusted using yet another LM358N op amp. In certain embodiments, the level is adjusted to allow for the signal going to the switch 320 to be a correct level to close the switch 320, such as when switch 320 is a MOSFET. After the level shift has occurred the signal passes through an output filter. In some embodiments, such as the one depicted in FIG. 3B, the output filter is a simple parallel resistor-capacitor filter (RC filter).

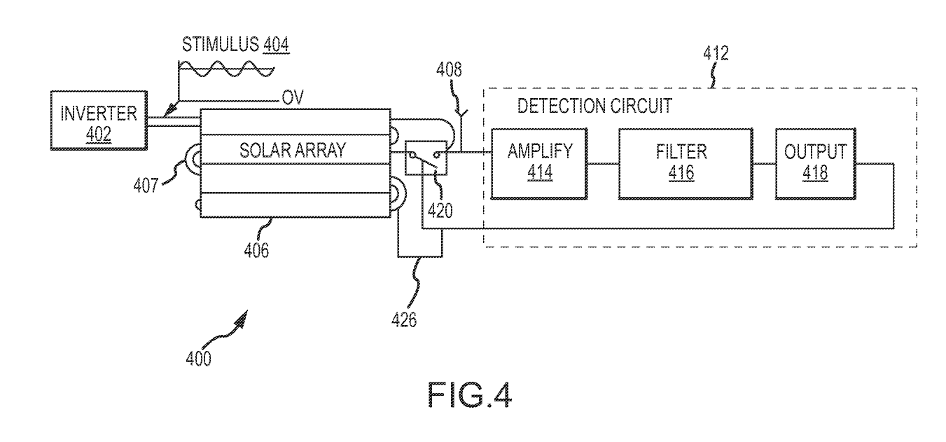

FIG. 4 depicts another embodiment of a solar array system with a discontinuity detection and suppression system 400. The basic elements of system 400 are substantially similar to the basic elements of system 300 depicted in FIG. 3A. However, system 400 differs from system 300 in that the detection circuit 412 and the switch 420 in system 400 are not powered by a discrete power source 322 or a power generation cell 324. Instead, the detection circuit 412 and the switch 420 draw power from the solar array circuit 407 itself, as indicated by connection 426. In certain embodiments, a voltage regulator circuit may be used to handle the broad range of voltages that may be generated by solar array 406. In embodiments where there is a detection circuit 412 and a switch 420 on each row of the solar array, each row of the solar array circuit may power the detection circuit 412 and the switch 420 on each row, respectively.

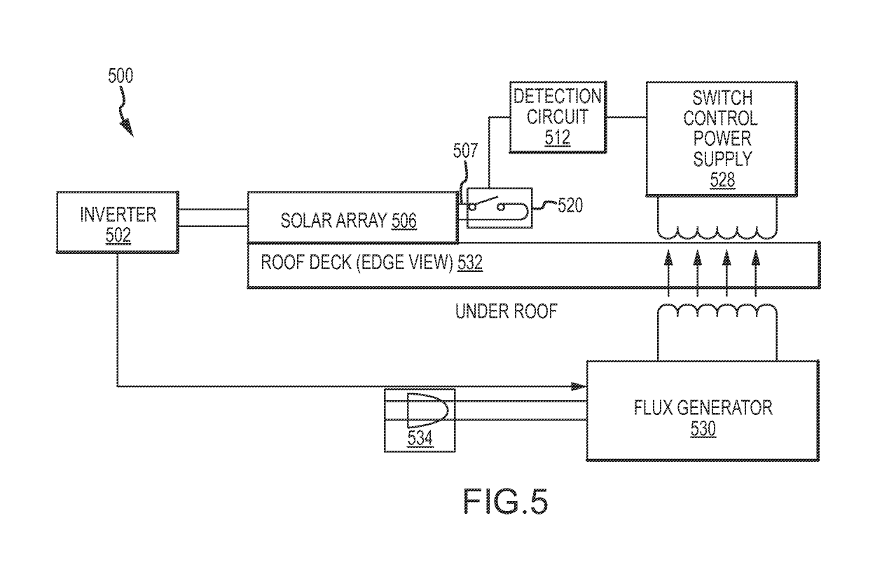

FIG. 5 depicts an embodiment of a solar array system with a discontinuity detection and suppression system 500. The basic elements of system 500 are substantially similar to the basic elements of system 300 depicted in FIG. 3A. In this embodiment, however, the detection circuit 512 and the switch 520 are powered by yet another source. System 500 includes an inverter 502, a solar array 506 with a solar array circuit 507, a switch 520, a detection circuit 512, a switch control power supply 528, a flux generator 530, and a flux generator power supply 534. The flux generator 530 and switch control power supply 528 are located on opposite sides of the roof deck 532. Magnetic flux coupled through the roof deck 532 is used to power the detection circuit 512 and the switch 520. This method of powering the components reduces or eliminates the need to pass additional wires through the roof deck 532. A magnetic field is generated by the flux generator 530 and passes through the roof deck 532. This magnetic field may be generated by passing current though an inductor or a solenoid in flux generator 530, or by any other known methods or systems. Once the magnetic field has passed through the roof deck 532, it reaches the switch control power supply 528, where the magnetic field is used to generate power. For example, the magnetic field may pass through a second inductor in switch control power supply 528, thus generating an electric current from the switch control power supply 528. The power produced from switch control power supply 528 is then utilized by the detection circuit 512 and the switch 520.

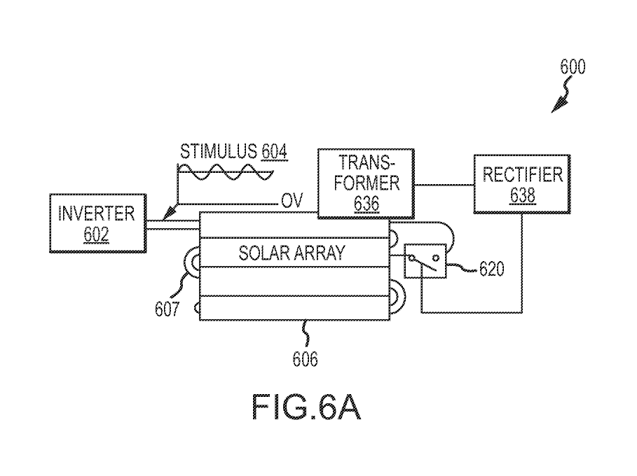

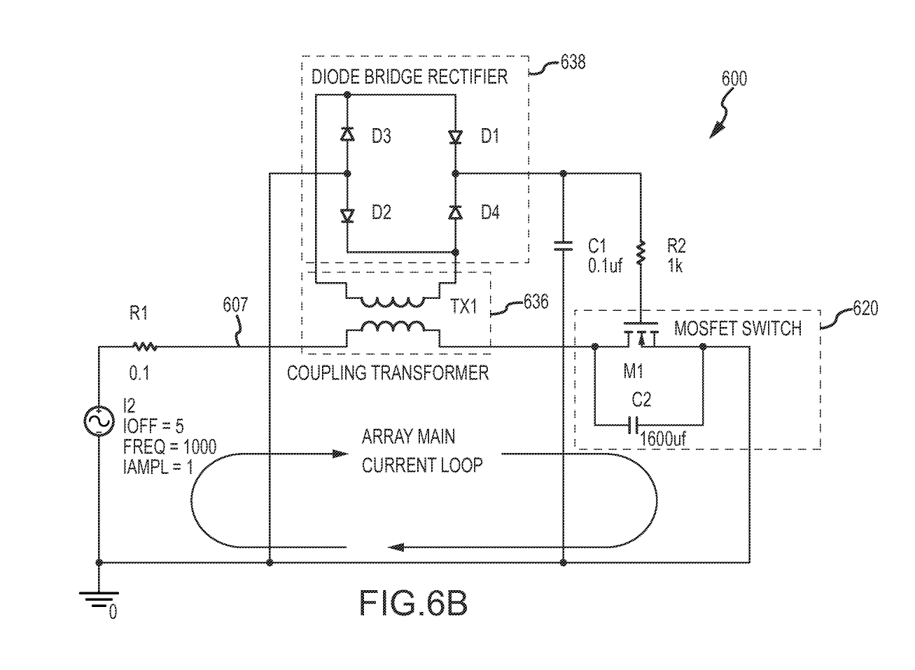

FIGS. 6A and 6B depict a circuit for detecting a discontinuity and suppressing a current within a solar array system 600. Several differences between system 600 and the previously described system are next described. As depicted in FIG. 6A, system 600 includes an inverter 602 that routes a continuity signal or a stimulus 604 onto a solar array circuit 607. The stimulus 604 may be an AC signal or another signal that has changing voltage and/or current. A transformer 636 is also attached to the solar array circuit 607 and is connected to a rectifier 638. The transformer 636 will only transmit changing signals, such as an AC signal, from the solar array circuit 607 to the rectifier 638. As noted above, however, a DC signal is generated by array 606. Thus, when the stimulus 604 is routed onto the solar array circuit 607, the only that stimulus signal 604 will pass to the rectifier 638 via the transformer 636. When the stimulus 604 is passed from the transformer 636 to the rectifier 638, the rectifier 638 rectifies the signal prior to sending it, or allowing it to pass, to the switch 620. Again, many different types of switches, such as mechanical, solid-state, and computer-controlled switches would be suitable for the switch 620. Where the continuity signal 604 is present on the solar array circuit 607, the switch 620 closes or remains closed, thus forming a closed solar array circuit 607. Where the continuity signal or stimulus 604 is absent, the switch opens, causing the solar array circuit 607 to open, which prevents current from flowing.

One example of a circuit for detecting a discontinuity and suppressing a current within a solar array system 600 is depicted in FIG. 6B. There, 12 represents the inverter 602 and R1 represents the solar array load. The switch 620 includes a MOSFET switch, and the transformer 638 is a toroid type transformer. The current from the solar array circuit 607 runs through the primary winding of the transformer 636 and then through the switch 620 when the switch 620 is closed. When switch 620 is open, DC current will not flow through the main solar array circuit 607. In this embodiment, the rectifier 638 is a standard full-wave bridge rectifier including four diodes, but other devices to rectify the signal may be utilized. The rectifier 638 is attached to the secondary winding of the transformer 636 and to the switch 620. Because the transformer 636 will couple only the stimulus signal 604, not the DC signal generated by the array 606, only the stimulus 604 will reach the rectifier 638. After the stimulus 604 has been rectified by the rectifier 638, the signal will be a DC signal with appropriate current and voltage levels as to keep the switch 620 closed. As depicted in FIG. 6B, the rectified signal is delivered to the drive gate of the MOSFET, effectively closing the switch 620, or turning on the MOSFET. When no stimulus 604 is present, no signal will be coupled by the transformer 636, and the switch 620 will open.

The ratio of primary windings to secondary windings on the transformer 636 may be selected to produce a sufficient voltage on the secondary winding to close the switch 620. In embodiments that utilize a diode bridge rectifier, it may be desirable to implement diodes that are fast enough to handle the selected stimulus signal 604. Additionally the rectified output may be filtered prior to reaching the switch 620. Also, a capacitor may be placed across the MOSFET to allow the MOSFET to close after is has been opened. This capacitor is depicted as C2 in FIG. 6B. By including this capacitor, AC current, such as the stimulus 604, will be able to pass through the solar array circuit when the switch 620 is open.

Additional elements or components may be added to the system 600 as desired. Filtering and signal conditioning components between the secondary winding of the transformer 636 and the switch 620 may be used to detect if the alternating current coupled by the transformer 636 matches the stimulus signal 604. If the coupled solar array signal from the solar array circuit 607 does not match the characteristics of the stimulus signal 604, it may be filtered out, preventing the switch 620 from closing based on an incorrect signal, such as electrical noise. Also, where a MOSFET is used as the switch 620, a deadband may be added to the gate drive of the MOSFET to ensure that the MOSFET would be fully on or fully off. Adding the deadband would also prevent linear responses in the MOSFET which can cause the MOSFET to overheat. Many of the components depicted in FIGS. 6A and 6B can be housed in a starter piece that may be located directly on the solar array 606, under the solar array 606, or integrated into a piece of flashing adjacent to the solar array 606. Also, system 600 does not need external power to power the switch 620. Instead, the power for the switch 620 control comes directly from the stimulus signal 604 itself.

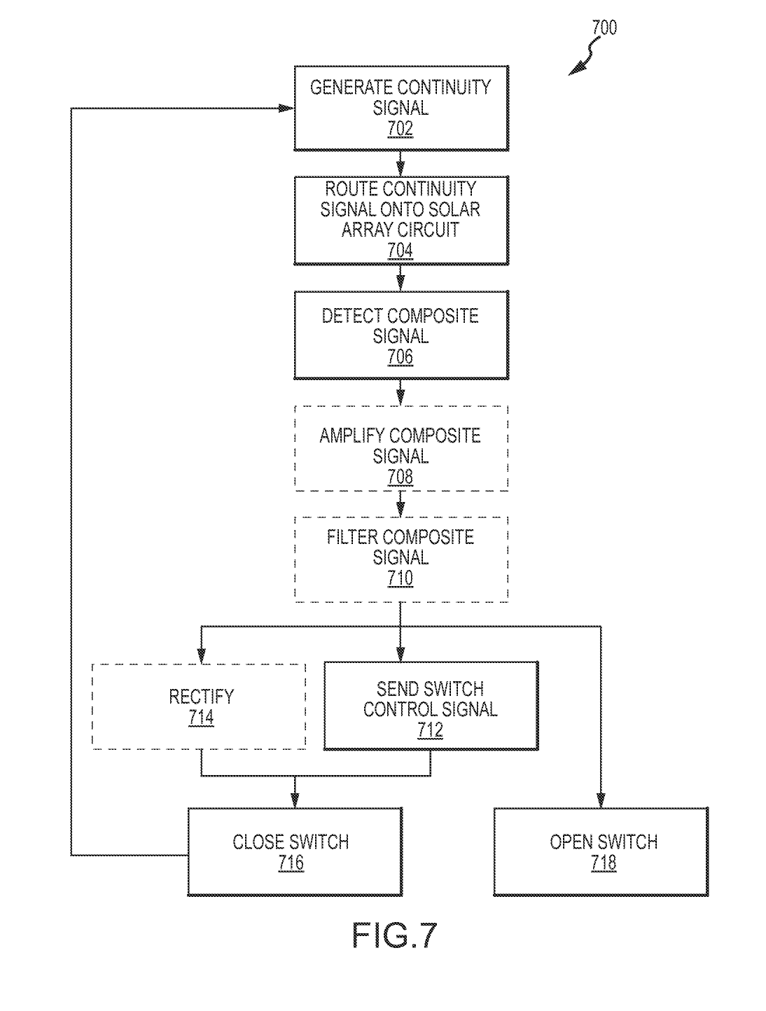

FIG. 7 depicts a method 700 for detecting a discontinuity and suppressing a current in solar array systems. Method 700 begins at operation 702. At operation 702, a stimulus or continuity signal is generated, for example, by a continuity signal generator such as the inverter or a separate component. The continuity signal may also be generated by a separate test signal generator for testing the solar array circuit. The continuity signal generator may also be controlled manually or remotely, via the interne or other communication network, allowing a user to discontinue the continuity signal for any reason. After the continuity signal is generated, the continuity signal is then routed onto the solar array circuit at operation 704. At operation 706, the composite signal, or solar array signal, is detected. The composite signal includes any signal or signals that are on the solar array circuit, such as the signals generated by the solar generation power modules. Thus, when the continuity signal has been routed onto the solar array circuit, the composite signal includes the continuity signal. Under certain circumstances, no other signals may be present on the solar array circuit, thus making the composite signal identical to the continuity signal. This may occur when the system is being tested and a test continuity signal is generated without the solar array circuit also generating power. The detection of the composite signal at operation 706 may be performed as described herein. For example, the signal could be detected by coupling the signal with a transformer, using an antenna, or having a hard-wire connection from the solar array circuit to a detection circuit. Once the composite signal has been detected at operation 706, in some embodiments, the detected composite signal may be amplified at operation 708 and filtered at operation 710, if such functionality is included in the system.

At operation 712, a control signal is sent to the switch indicating that the switch should close. In certain embodiments, the control signal is generated when the continuity signal is detected. In other embodiments, the control signal is the continuity signal itself, or derived therefrom. For example, where the continuity signal is present, that signal may be modified in some manner and passed to the switch as a control signal indicating that the switch should close or remain closed. In other embodiments, the control signal is rectified, as depicted at operation 714. Where the control signal is present, it may be rectified before it is passed to the switch. The rectified control signal indicates to the switch that the switch should close or remain closed.

At operation 716, the switch receives the control signal or the continuity signal indicating that the switch should be closed or remain closed. Upon receipt of the control signal or the continuity signal, the switch closes or remains closed. For example, where the switch is a MOSFET, the MOSFET receives the control signal or rectified continuity signal on its gate drive, which powers on the MOSFET to close the switch. Where the continuity signal is not present in the composite signal, no control signal will be sent. Thus, in the absence of the continuity signal, the switch will open or remain open at operation 718. By opening the switch, direct current will not flow through the solar array circuit and any potential arcs located thereon will be suppressed.

In certain embodiments, the detection and suppression systems disclosed herein may be integrated into a solar array system of BIPV or other solar articles. One detection and suppression system or circuit may be used for a single array. Alternatively, multiple detection and suppression systems may be used in a single array, for example, a detection and suppression system may be incorporated into a subset of solar cells in an array. In one embodiment, a detection and suppression system may be included in each row of a multi-row array. In multiple detection system arrays, the detectors may be configured such that detection of an arc event by a single detector may initiate arc suppression in all suppression devices.

The detection and suppression system described above may be sold as a kit, either in a single package or in multiple packages. A kit may include the various components described above in the various systems, or each of these components may be sold separately. Each system includes a plurality of connectors for communication with the other components of the array. If desired, wiring may be included, although instructions included with the kit may also specific the type of wiring required based on the particular installation. Additionally, systems may be loaded with or include the necessary software or firmware required for use of the system. In alternative configurations, software may be included on various types of storage media (CDs, DVDs, USB drives, etc.) for upload to a standard PC, if the PC is to be used as the array performance monitor, or if the PC is used in conjunction with the array performance monitor as a user or service interface. Additionally, website addresses and passwords may be included in the kit instructions for programs to be downloaded from a website on the internet.

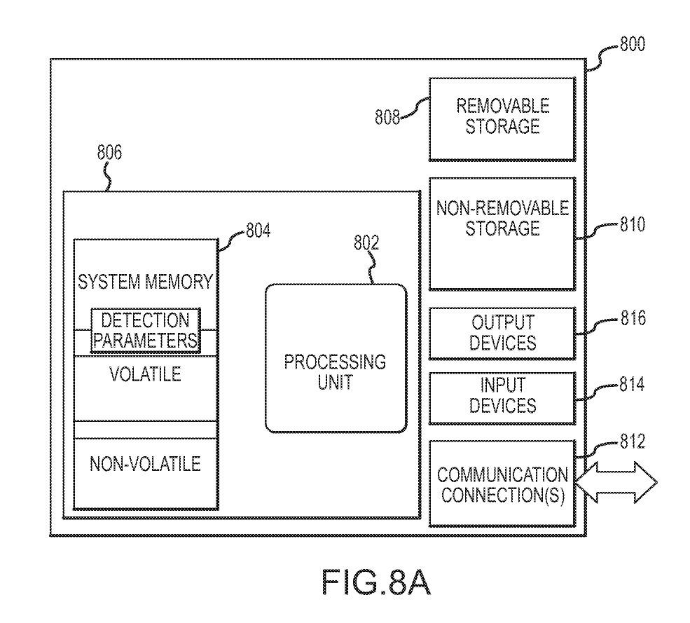

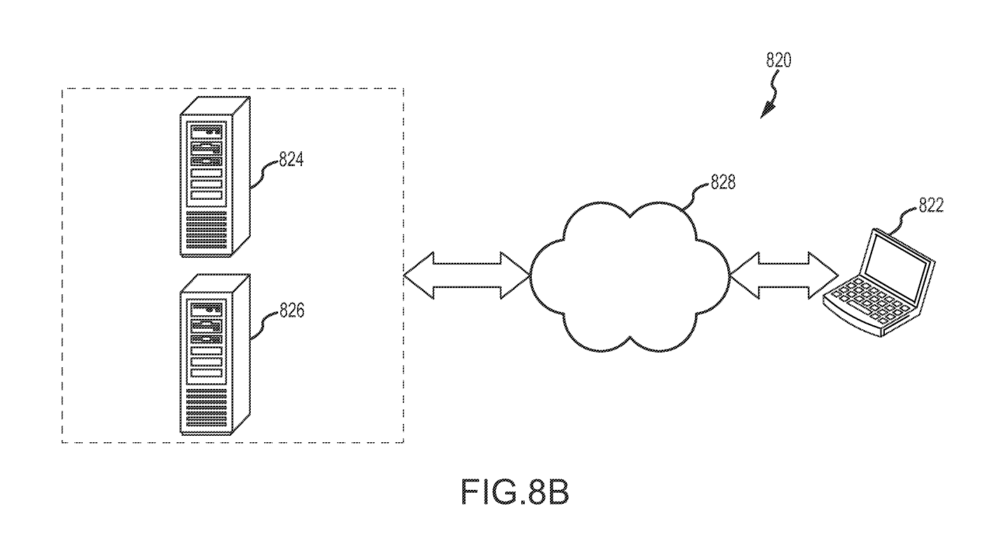

FIG. 8A and the additional discussion in the present specification are intended to provide a brief general description of a suitable computing environment in which the present invention and/or portions thereof may be implemented. Although not required, the embodiments described herein may be implemented as computer-executable instructions, such as by program modules, being executed by a computer, such as a client workstation or a server, including a server operating in a cloud environment. Generally, program modules include routines, programs, objects, components, data structures and the like that perform particular tasks or implement particular abstract data types. Moreover, it should be appreciated that the technology and/or portions thereof may be practiced with other computer system configurations, including hand-held devices, multi-processor systems, microprocessor-based or programmable consumer electronics, network PCs, minicomputers, mainframe computers and the like. The invention may also be practiced in distributed computing environments where tasks are performed by remote processing devices that are linked through a communications network. In a distributed computing environment, program modules may be located in both local and remote memory storage devices.

FIG. 8A illustrates one example of a suitable operating environment 800 in which one or more of the present embodiments may be implemented. This is only one example of a suitable operating environment and is not intended to suggest any limitation as to the scope of use or functionality. Other well-known computing systems, environments, and/or configurations that may be suitable for use include, but are not limited to, personal computers, server computers, hand-held or laptop devices, multiprocessor systems, microprocessor-based systems, programmable consumer electronics such as smartphones, network PCs, minicomputers, mainframe computers, distributed computing environments that include any of the above systems or devices, and the like.

In its most basic configuration, operating environment 800 typically includes at least one processing unit 802 and memory 804. Depending on the exact configuration and type of computing device, memory 804 (storing, among other things, continuity signal parameters and/or instructions to provide control signals described herein) may be volatile (such as RAM), non-volatile (such as ROM, flash memory, etc.), or some combination of the two. Memory 804 may store computer instructions related to, inter alia, provide system control signals, continuity detection parameters, etc., as disclosed herein. Memory 804 may also store computer-executable instructions that may be executed by the processing unit 802 to perform the methods disclosed herein.

This most basic configuration is illustrated in FIG. 8A by line 806. Further, environment 800 may also include storage devices (removable, 808, and/or non-removable, 810) including, but not limited to, magnetic or optical disks or tape. Similarly, environment 800 may also have input device(s) 814 such as keyboard, mouse, pen, voice input, etc. and/or output device(s) 816 such as a display, speakers, printer, etc. Also included in the environment may be one or more communication connections 812, such as LAN, WAN, radio frequencies, point to point, etc. Communication between the various components of the system may be performed using communication connections 812.

Operating environment 800 typically includes at least some form of computer readable media. Computer readable media can be any available media that can be accessed by processing unit 802 or other devices comprising the operating environment. By way of example, and not limitation, computer readable media may comprise computer storage media and communication media. Computer storage media includes volatile and nonvolatile, removable and non-removable media implemented in any method or technology for storage of information such as computer readable instructions, data structures, program modules or other data. Computer storage media includes, RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information. Communication media embodies computer readable instructions, data structures, program modules, or other data in a modulated data signal such as a carrier wave or other transport mechanism and includes any information delivery media. The term “modulated data signal” means a signal that has one or more of its characteristics set or changed in such a manner as to encode information in the signal. By way of example, and not limitation, communication media includes wired media such as a wired network or direct-wired connection, and wireless media such as acoustic, RF, infrared and other wireless media. Combinations of the any of the above should also be included within the scope of computer readable media.

Control instructions for operating the detection and suppression system may be stored in system memory 804. Processing unit 802 may execute control instructions to provide the desired stimulation. The operating environment 800 may be a single computer operating in a networked environment using logical connections to one or more remote computers. The remote computer may be a personal computer, a server, a router, a network PC, a peer device or other common network node, and typically includes many or all of the elements described above as well as others not so mentioned. The logical connections may include any method supported by available communications media. Such networking environments are commonplace in offices, enterprise-wide computer networks, intranets and the Internet.

FIG. 8B is an embodiment of a network 820 in which the various systems and methods disclosed herein may operate. In embodiments, a client device, such as client device 822, may communicate with one or more servers, such as servers 824 and 826, via a network 828. In embodiments, a client device may be a laptop, a personal computer, a smart phone, a PDA, a netbook, or any other type of computing device, such as the computing device in FIG. 7A. In embodiments, servers 824 and 826 may be any type of computing device, such as the computing device illustrated in FIG. 7A. Network 828 may be any type of network capable of facilitating communications between the client device and one or more servers 824 and 826. Examples of such networks include, but are not limited to, LANs, WANs, cellular networks, and/or the Internet.

In embodiments, the various systems and methods disclosed herein may be performed by one or more server devices. For example, in one embodiment, a single server, such as server 824 may be employed to perform the systems and methods disclosed herein. Client device 822 may include one or more of the implant, the remote device, or the external interface unit, which may communicate with each other using one or more of network 828 and servers 824 and 826.

In alternate embodiments, the methods and systems disclosed herein may be performed using a distributed computing network, or a cloud network. In such embodiments, the methods and systems disclosed herein may be performed by two or more servers, such as servers 824 and 826. Although a particular network embodiment is disclosed herein, one of skill in the art will appreciate that the systems and methods disclosed herein may be performed using other types of networks and/or network configurations.

While there have been described herein what are to be considered exemplary and preferred embodiments of the present technology, other modifications of the technology will become apparent to those skilled in the art from the teachings herein. The particular methods of manufacture and geometries disclosed herein are exemplary in nature and are not to be considered limiting. It is therefore desired to be secured in the appended claims all such modifications as fall within the spirit and scope of the technology. Accordingly, what is desired to be secured by Letters Patent is the technology as defined and differentiated in the following claims, and all equivalents.

What is claimed is:

1. A solar array kit useful in forming a solar array system, the kit comprising:
a continuity signal generator comprising connectors for connecting a solar array circuit, wherein the continuity signal generator is adapted to deliver a continuity signal to the solar array circuit; and
a detection circuit comprising connectors for connecting to the solar array circuit, the detection circuit comprising:
a continuity signal sensor;
at least one switch for selectively opening and closing the solar array circuit; and
a switch controller operatively connected to the switch and the continuity signal sensor, wherein the switch controller comprises a connector for connecting to a power source, and wherein the switch controller is adapted to actuate the switch upon receipt of a control signal from the detection circuit.

2. The solar array kit of claim 1, further comprising at least one solar cell comprising connectors for connecting to the solar array circuit and the detection circuit.

3. The solar array kit of claim 1, wherein the control signal comprises the continuity signal.

4. The solar array kit of claim 1, wherein the detection circuit further comprises an amplifier for amplifying a solar array signal and a filter for filtering the solar array signal, and wherein the solar array signal comprises the continuity signal.

5. The solar array kit of claim 1, wherein the switch controller connector is adapted to connect to a power source discrete from the solar array circuit.

6. The solar array kit of claim 1, wherein the switch controller connector is adapted to connect to the solar array circuit, wherein the solar array circuit is adapted to deliver power to the switch.

7. The solar array kit of claim 5, wherein the power source discrete from the solar array circuit comprises at least one of:
discrete solar power generation cell comprising connectors for connecting to the switch controller connector; and
a magnetic flux generator comprising a first inductor and a second inductor, the first inductor and second inductor arranged so as to generate a magnetic flux between the first inductor and the second inductor, and wherein the second inductor comprises connectors for connecting to the switch controller connector.

8. The solar array kit of claim 1, wherein the at least one switch comprises at least one of a metal-oxide-semiconductor field-effect transistor, a solid-state switch, and a mechanical switch.

9. The solar array kit of claim 1, wherein the continuity signal sensor comprises at least one of a transformer, an antenna, and a hard-wire connection.

10. A method for maintaining a solar array circuit, the method comprising:
detecting a solar array signal on a solar array circuit; and
sending a control signal to a solar array circuit switch, based on the presence of a continuity signal in the solar array signal.

11. The method of claim 10, further comprising:
generating the continuity signal; and
routing the continuity signal onto the solar array circuit.

12. The method of claim 11, further comprising closing the solar array circuit upon receipt of the control signal.

13. The method of claim 10, wherein the control signal comprises the continuity signal.

14. The method of claim 10, wherein the solar array signal comprises a direct current component, and wherein the continuity signal comprises an alternating current component.

15. The method of claim 10, wherein the solar array signal is generated by at least one solar cell.

16. The method of claim 10, further comprising at least one of filtering the detected solar array signal, amplifying the detected solar array signal, and rectifying the detected solar array signal.

17. The method of claim 10, further comprising delivering power to the switch from a power source discrete from the solar array circuit.

18. The method of claim 17, wherein the power source comprises at least one of a solar cell discrete from the solar array circuit, a magnetic flux generator, and a building power service.

19. The method of claim 10, further comprising delivering power to the switch from the solar array circuit.

20. The method of claim 10, wherein the solar array signal is detected via at least one of an antenna, a transformer, and a hard-wire connection.
